(19) United States
(12) Patent Application Publication
(10) Pub. No.: US 2002/0027242 A1
(43) Pub. Date: Mar. 7, 2002

(54) Arrangemenet in a power MOS transistor

(76) Inventors: Mikael Zackrisson, Rimbo (SE); Nils af Ekenstam, Solna (SE); Jan Johansson, Upplands Vasby (SE)

Correspondence Address: NIXON & VANDERHYE P.C., 1100 North Glebe Road, 8th Floor, Arlington, VA, 22201, US

(21) Appl. No.: 09/918,726

(22) Filed: Aug. 1, 2001

(30) Foreign Application Priority Data
Aug. 4, 2000 (SE) 0002828-2

(51) Int. Cl. H01L 29/76

(52) U.S. Cl. 257/332

(57) ABSTRACT

To reduce parasitic capacitances between drain and source electrodes, respectively, and gate electrodes in a power MOS transistor, the drain and the source electrodes (D′, S′) are located below the gate electrodes (G) in the transistor.

### TECHNICAL FIELD

The invention relates generally to power MOS transistors and more generally to an arrangement for reducing parasitic capacitances in such transistors.

### BACKGROUND OF THE INVENTION

Parasistic capacitances have a negative influence on the performance of e.g. an LDMOS transistor, i.e. on its output power, gain and efficiency. In order to improve the performance, current drive capability and transconductance of the transistor should be maximized at the same time as parasitic capacitances between gate and source, drain and source, and gate and drain of the transistor should be minimized.

It is most important to minimize the parasitic capacitance between the gate and the drain since that parasitic capacitance provides a negative feedback path from the output to the input (drain to gate) of the transistor. However, reduction of the parasitic capacitance between the gate and the source is also important in order to maximize gain performance over a given bandwidth. Moreover, reduction of the parasitic capacitance between the drain and the source improves efficiency.

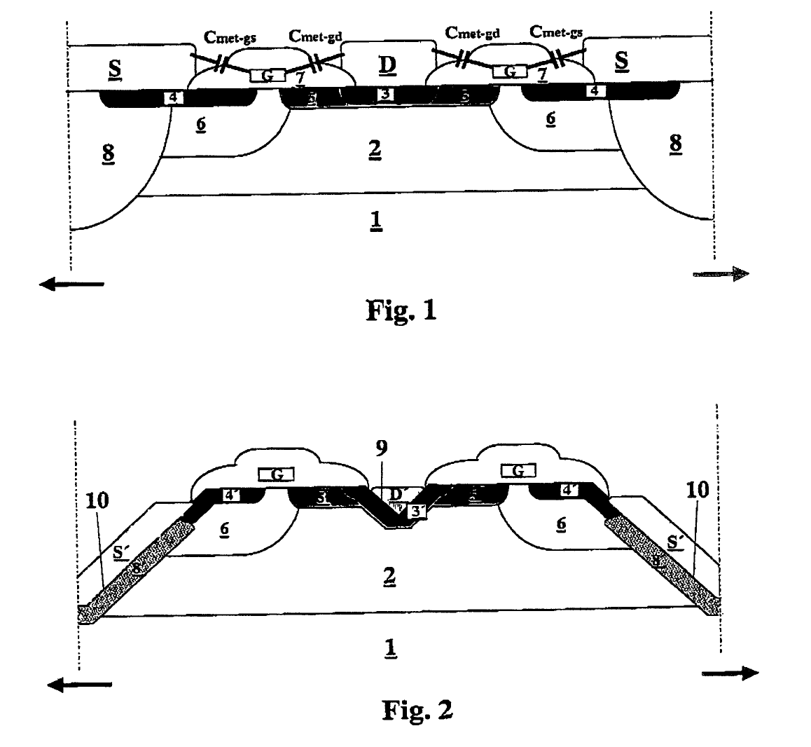

FIG. 1 is a cross-sectional view of part of a typical LDMOS transistor. The transistor pattern repeats itself in the direction of the arrows to the left and right.

In a manner known per se, the transistor is built into a p+ silicon substrate 1 with a p-epitaxial layer 2 on its one side and a source metal layer (not shown) on its other side.

N+ source regions 4 and drain regions, each comprising an n+ drain contact region 3 surrounded on both sides by n- drift regions 5, are provided in the p- layer 2. A drain metal finger or electrode D) is provided on top of the n+ drain contact region 3.

Gate fingers or electrodes G are embedded in dielectric layers 7 on both sides of the drain electrode D on top of the p- layer 2. A p-well 6 is diffused laterally under each gate electrode G from its source side.

Deep diffused p+ regions 8 allow for current to pass from the n+ source regions 4 to the p+ substrate 1 with minimal voltage drop by means of source electrodes S that short-circuit the n+ source regions 4 and the p+ regions 8.

In an LDMOS transistor according to FIG. 1, parasitic capacitances are formed between each drain electrode D and each gate electrode G as well as between each source electrode S and each gate electrode G.

In FIG. 1, a parasitic capacitance Cinet-gd is shown between the side wall of the gate electrode G and the drain electrode D. This parasitic capacitance Cmet-gd is a major contributor to the total value of the parasitic capacitance between the gate and the drain.

Also in FIG. 1, a parasitic capacitance Cmet-gs is shown between the source electrode S and the side wall of the gate electrode G. This parasitic capacitance Cmet-gs contributes relatively little to the total value of the parasitic capacitance between the gate and the source.

U.S. Pat. No. 5,252,848 discloses a conductor functioning as an extended source electrode in a field effect transistor to provide the transistor with a small gate-to-drain capacitance.

A negative effect of that conductor in U.S. Pat. No. 5,252,848 is, however, that the parasitic capacitance between the gate electrode and the source electrode increases as the conductor is wrapped around the entire gate. Moreover, a new contribution to the total value of the parasitic capacitance between the drain electrode and the source electrode appears between the side walls of drain electrode and the conductor in U.S. Pat. No. 5,252,848.

Another negative side effect of the conductor in U.S. Pat. No. 5,252,848, extending over part of the n- drift region, is that it will produce a drain voltage dependant variation of the resistivity of the n- drift region that will degrade linearity performance of the transistor.

### SUMMARY OF THE INVENTION

The object of the invention is to simultaneously reduce the parasitic gate-to-drain capacitance and the parasitic gate-to-source capacitance in a power MOS transistor.

This is attained in accordance with the invention preferably by means of “lowered” drain and source electrodes, i.e. electrodes whose top surface is below the gate electrode.

Hereby, both the parasitic gate-to-drain capacitance and the parasitic gate-to-source capacitance will be reduced simultaneously.

### BRIEF DESCRIPTION OF THE DRAWING

The invention will be described more in detail below with reference to the appended drawing on which FIG. 1 described above, is a cross-sectional view of a known LDMOS transistor, and FIG. 2 is a cross-sectional view of an embodiment of an LDMOS transistor according to the invention.

### DESCRIPTION OF THE INVENTION

In accordance with the invention, to simultaneously reduce the parasitic gate-to-drain capacitance and the parasitic gate-to-source capacitance in a power MOS transistor, the drain electrode and the source electrode are located below the gate electrode in the transistor.

A cross-sectional view of an embodiment of a power LDMOS transistor according to the invention is shown in FIG. 2.

Elements that are identical in FIGS. 1 and 2 are provided with the same reference characters.

In the embodiment shown, both a triangular drain electrode D′ and a V-shaped source electrode S′ are recessed in the silicon substrate 1 to be located below the gate electrode G.

This has been accomplished by first producing a V-groove 9 for the drain electrode D in the p- epitaxial layer 2, and a V-groove 10 for the source electrode S- in the p- epitaxial layer 2 and down into the silicon substrate 1 by e.g. wet etching.

Before the drain electrode D is placed in its V-groove 9, a drain region comprising an n drift region 5′, extending along the top surface of the p- layer 2 as well as along the side walls of the V-groove 9, and an n+ drain contact region 3′, extending along the walls of the V-groove 9 on top of the n- drift region 5′ up to the top surface of the p- layer 2, is provided in the V-groove 9 in the p- layer 2.

Before the source electrode S′ is placed in its V-groove 10, an n+ source region 4′ that partly extends along a wall of the V-groove 10 and partly along the top surface of the p-layer 2, is produced as well as a V-shaped diffused p+ region 8′ extending along the wall of the V-groove 10 into its bottom.

Hereby, both the parasitic gate-to-drain capacitance and the parasitic gate-to-source capacitance in the power LDMOS transistor are reduced simultaneously since there are no drain or source electrode side walls facing the gate electrode side walls.

The V-groove 10 for the source electrode S′ is also used to produce a low resistance path from the n+ source region 4′ to the p+ substrate 1 by means of the relatively shallow p+ diffusion region 8′ that replaces the deep p+ diffusion 8 in the known transistor in FIG. 1.

There are other ways of locating the drain electrode and the source electrode lower than the gate electrode in the transistor to achieve the same purpose.

To save space, trenches (not shown), i.e. grooves with more vertical side walls, can be used instead of V-grooves.

However, it is more difficult to introduce p+ and n+ dopants into the side walls of such trenches.

Instead of lowering the source and drain electrodes relative to the gate electrode, it is an alternative to instead elevate the gate electrode relative to the source and drain electrodes by using e.g. selective epitaxial growth.

It is to be understood that since it is more important to reduce the parasitic gate-to-drain capacitance than the parasitic gate-to-source capacitance, there are applications where only the drain electrode is located below the gate electrode while the source electrode remains unchanged. In such a case, there would only be a V-groove 9 for the drain electrode D′ in FIG. 2.

1. An arrangement for reducing parasitic capacitances between drain and source electrodes, respectively, and gate electrodes in a power MOS transistors characterized in that at least the drain electrodes (D) are located below the gate electrodes (G) in the transistor.

2. The arrangement according to claim 1, characterized in that both the drain electrodes (D′) and the source electrodes (S′) are located below the gate electrodes (G) in the transistor.

3. The arrangement according to claim 1, characterized in that at least the drain electrodes (D′) are located in V-grooves (9) in the silicon.

4. The arrangement according to claim 2, characterized in that both the drain electrodes (D′) and the source electrodes (S′) are located in V-grooves (9, 10) in the silicon.

5. The arrangement according to claim 1, characterized in that the gate electrodes are elevated relative to the source and drain electrodes.
